(19) United States
(12) Patent Application Publication
(10) Pub. No.: US 2017/0142393 A1
(43) Pub. Date: May 18, 2017

(54) Structured Light Imaging System and Method

(71) Applicant: Heptagon Micro Optics Pte. Ltd., Singapore (SG)

(72) Inventor: Thierry OGGIER, Zurich (CH)

(21) Appl. No.: 15/320,107

(22) PCT Filed: Jun. 23, 2015
(86) PCT No.: PCT/SG2015/050177

§ 371 Date: Dec. 19, 2016

(30) Foreign Application Priority Data
Jun. 27, 2014 (CH) 00976/14

(51) Int. Cl. H04N 13/00; H04N 13/02; G01B 11/25

(52) U.S. Cl. CPC H04N 13/0022; G01B 11/2513; H04N 13/02; H04N 13/0296; H01S 5/423

(57) ABSTRACT

The present invention relates to a structured light imaging system and method. The structured light imaging system and method is adapted to include a projector with at least two groups of light emitters and an image sensor with an array of pixel, wherein a controller is configured to enable that each group is operated individually. In a variant, each pixel of the image sensor allocates one storage node to each of the at least two group of light emitters.

### FIELD OF THE INVENTION

The present invention relates to imaging systems and methods, and, more particularly, to structured light imaging systems and methods. It relates also to methods and apparatuses for determining depth maps of scenes.

### BACKGROUND ART

Many depth sensing measurement systems (also known as 3D imaging systems or 3D cameras) rely on the triangulation principle. One of the most common methods in active triangulation systems is to use an emitter (or projector) and a receiver, both physically separated from each other to build the base length of the triangulation system. The projector may provide a structured illumination. The structured illumination is understood in this context as a spatially coded or modulated illumination. The receiver comprises an image sensor with an array of pixels. A controller typically processes the raw image acquired by the receiver and derives a three-dimensional depth map of the acquired objects, scene or people. Such systems are generally known as structured light imaging systems. The structured illumination may have any regular shape, e.g. lines or circles, or may have a pseudo-random pattern such as pseudo-random dot patterns or further may have pseudo-random shapes or sizes of shapes. The implementation and use of such a pseudo-random but regular pattern in a projector of a structured light imaging system has been published in PCT publication WO2007/105205A2 and has been widely adapted in gaming industry. A new type of a projector for use in a structured light imaging based on many light emitting laser diodes on the same die and projected into the 3D space are presented in US2013/0038881A1 and WO2013127974A1. The formation of the pattern of the projection already on the light emitting solid-state device has the advantage of being highly energy efficient. E.g. in case of a random dot pattern, all the generated light is inherently bundled into the dots. There is no loss in between the dots. On the other side, building a projector based on imprinted transparencies, masks or micro-mirror arrays such as digital light processors (DLP), the light between dots is blocked or deviated. Therefore, a large amount of the generated optical power is lost. Other projectors are based on a single collimated laser diode and one or several diffractive optical elements. These types of projectors show a good efficiency, but it is extremely challenging to keep the pattern stable enough over a large temperature range to perform reasonable depth measurement based on structured light imaging. To cope with such thermal shortcomings parts of the pattern projector may be temperature controlled, e.g. by using Peltier elements or heating resistors, thus reducing the overall energy efficiency.

Another improvement for a structured light imaging system based on a temporally coded structured light source and image sensor has been proposed in the European publication EP2519001A2. Applying temporal coding on a structured light imaging system enables to subtract background light either on-pixel, in case the pixel on the image sensor can perform differential imaging, or off-pixel as post-processing of the image. Further, temporal coding or modulation enables multi-camera operation. This means different structured light imaging systems can apply temporal coding and, by doing so, can operate within the same environment without interfering with each other. Specific temporal coding approaches that can operate with limited interferences are e.g. based on code division multiple access, frequency division multiple access or others such as frequency or phase hopping.

### DISCLOSURE OF THE INVENTION

It can be an object of this invention, to provide a highly efficient structured light imaging system with improved depth and lateral resolution as well as a corresponding method and an apparatus and a method for depth mapping a scene. A structured light imaging system can also be understood as a structured light imaging apparatus.

These objectives are achieved particularly through the features of the independent claims. In addition, further advantageous embodiments follow from the dependent claims and the description.

In a first view, the structured light imaging apparatus comprises a projector comprising at least two groups of light emitters for emitting structured light, an image sensor for sensing light originating from the projector, and a control unit.

The controller is structured and configured for individually operating each group of the at least two groups of light emitters.

In another view, the structured light imaging system includes an image sensor and a projector, wherein the projector includes at least two groups of light emitters, wherein a controller is configured to enable that each group is operated individually.

Both views can be mixed and interchanged.

In some embodiments of the present invention, a single light projecting device in the projector is configured to project structured light emitted by the at least two groups of light emitters onto a scene. It is advantageous and reduces processing and calibration complexity, if the patterns of the group of light emitters are projected by the same single light projecting device. This results in a constant combined pattern of the different group of light emitters, independent on the distance of the object in the scene. By having e.g. two physically separated light projecting devices in front of the group of light emitters, the different emitted patterns cross each other over the distance. Therefore, a single calibration acquisition at a single distance will not suffice to deduce disparities and measure distances based on triangulation.

In some embodiments of the present invention, the at least two groups of light emitters include vertical cavity surface emitting lasers (VCSEL). In some instances, VCSEL can be a suitable choice of light emitters, since the can be integrated in a small devices and due to their low cost and high volume manufacturability.

In some embodiments of the present invention, the at least two groups of light emitters are arranged on a single die. In case the at least two groups of light emitters are on the same die, it simplifies the design of the light projecting device.

In some embodiments of the present invention, the at least two groups of light emitters are arranged physically interlaced. Physical interlacing of the at least two groups of light emitters and the projection thereof allows to have more dense structures in the emitted structured light, hence, the spatial information derived from the structured light image enable higher lateral and depth resolutions.

In some embodiments of the present invention, the at least two groups of light emitters are arranged to emit the same, but displaced structured light pattern. By emitting the same but displaced structured light pattern by the at least two groups of light emitters, the result becomes more predictive than by emitting complete different pattern by the at least two groups of light emitters.

In some embodiments of the present invention, the at least two groups of light emitters are arranged to emit different structured light patterns. Emitting different structured light pattern e.g. emitting a random dot pattern and a line stripe pattern may increase the depth resolution. Further, combinations of different random dot patterns are imaginable.

In some embodiments of the present invention, the controller is configured to enable that the at least two groups of light emitters are operated in an interleaved mode. Since the controller can be configured to enable that each group is operated individually, it can be advantageous to interleave to operation of the different group of light emitters. Different schemes of interleaved operations are imaginable such a pseudo-noise operation, frequency hopping operation or others, dependent on the actual application. Interleaved operation can help to reduce interferences between structured light imaging systems and can reduce issues of fast moving objects in the present invention.

In some embodiments of the present invention, the image sensor includes an array of pixels, each pixel having a separate storage node per group of light emitters.

In some embodiments of the present invention, the controller is configured to enable that for each pixel of the image sensor one storage node per group of light emitters is allocated. It can be advantageous to have on each pixel of the image sensor a separate storage node per group of light emitters. This can enable to store the images of each group of light emitters in a separate storage node.

In some embodiments of the present invention, the pixels of the image sensor include a common signal removal circuitry configured to remove a common-mode signal of the storage nodes of the pixels on the image sensor. A common-mode signal removal on pixel level increases the dynamic range and enables to suppress background light.

In some embodiments of the present invention, the controller is configured to enable that at least two groups of light emitters are turned on alternately and repetitively during exposure, wherein the signal is integrated correspondingly on the allocated storage nodes of the pixels. The alternating and repeating operation of the group of light emitters and the corresponding signal integration in the allocated storage nodes in the pixels during exposure can help to reduce interferences with other structured light imaging system in the same surroundings and further reduces effects due to changing scenes during exposures.

In some embodiments of the present invention, the pixels of the image sensor are time-of-flight pixels. Most of the state-of-the-art time-of-flight pixels already contain two storage nodes and even an in-pixel common-mode removal circuitry. Therefore, instead of designing new pixels, one could build a structured light system according to the invention based on such time-of-flight pixel architectures.

In a first view, the structured light imaging method comprises providing a projector comprising at least two groups of light emitters, emitting structured light from the at least two groups of light emitters, wherein each of the groups of light emitters is operated individually, and sensing light originating from the projector by means of an image sensor.

In another view, the structured light imaging method comprises using an image sensor and a projector wherein the projector includes at least two groups of light emitters, each group of light emitters being operated individually.

Both views can be mixed and interchanged.

In a variant, that structured light emitted by the at least two groups of light emitters is projected through a single light projecting device onto the scene. In a variant, the at least two groups of light emitters are operated in an interleaved mode. In a variant, the at least two groups for each pixel of the image sensor one storage node per group of light emitters is allocated. In a variant, a common-mode signal of the storage nodes of the image sensor is removed. In a variant, that the at least two groups of light emitters are turned on alternately and repetitively during exposure, wherein the signal is integrated correspondingly in the allocated storage nodes of the pixels.

The method for depth mapping of a scene comprises
illuminating the scene with structured light from a projector comprising at least a first and a second group of light emitters;
the illuminating comprising operating each of the groups of light emitters individually;
detecting light portions of the structured light reflected from the scene;
determining a depth map of the scene from the detected light portions.

In another view, the method for depth mapping of a scene comprises
illuminating the scene by the aid of a structured light imaging apparatus (or system) of the herein-described kind;
detecting light portions of the structured light reflected from the scene by means of the structured light imaging apparatus (or system);
determining a depth map of the scene from the detected light portions.

The apparatus for determining a depth map of a scene comprises a structured light imaging apparatus (or system) of the herein-described kind for illuminating the scene with structured light and for detecting light portions of the structured light reflected from the scene. And it comprises a processing unit for determining the depth map of the scene from the detected light portions. The processing unit may be comprised in the controller of the structured light imaging apparatus.

### BRIEF DESCRIPTION OF THE DRAWINGS

The herein described invention will be more fully understood from the detailed description given herein below and the accompanying drawings which should not be considered limiting to the invention described in the appended claims. The drawings show

FIG. 1 a building block-diagrammatical illustration of a structured light imaging apparatus and method;

FIG. 2 a building block diagram of a pixel as it may be implemented in an embodiment of the invention;

FIG. 3 a top view on a light emitting component with two groups of light emitters as it may be implemented in an embodiment of the invention;

FIG. 4 a random dot pattern image resulting from light emitting component as illustrated in FIG. 3 in case both groups of light emitters are turned on at the same time (FIG. 4a) and in case each group of light emitters can be controlled separately (FIG. 4b);

FIG. 5 images reduced to two dots of a state-of-the-art structured light imaging system (FIGS. 5a to c), wherein the insets show an enlarged detail (top: rastered black-and-white, bottom: greyscale), and FIGS. 5d to f plot horizontal cross-sections of the signals across the dot centres from FIGS. 5a to c;

FIG. 6 images reduced to two dots of a structured light imaging system (FIGS. 6a to c), wherein the insets show an enlarged detail (top: rastered black-and-white, bottom: greyscale), and FIGS. 6d to f plot horizontal cross-sections of the signals across the dot centres from FIGS. 6a to c.

### MODE(S) FOR CARRYING OUT THE INVENTION

In prior art structured light imaging systems, the projector is either static, meaning always emitting the same pattern, or it includes some moving parts in the projector such as micro-mirrors (e.g. MEMS based digital light processor), or it includes local transparency changing devices such as liquid crystal devices. The latter two enable to change the pattern almost arbitrarily, but much of the emitted light is wasted due the light blocking nature of the approach. The present invention can, at least in instances, achieve a highly efficient structured light imaging system without any moving parts, better resolution, and increased temperature stability.

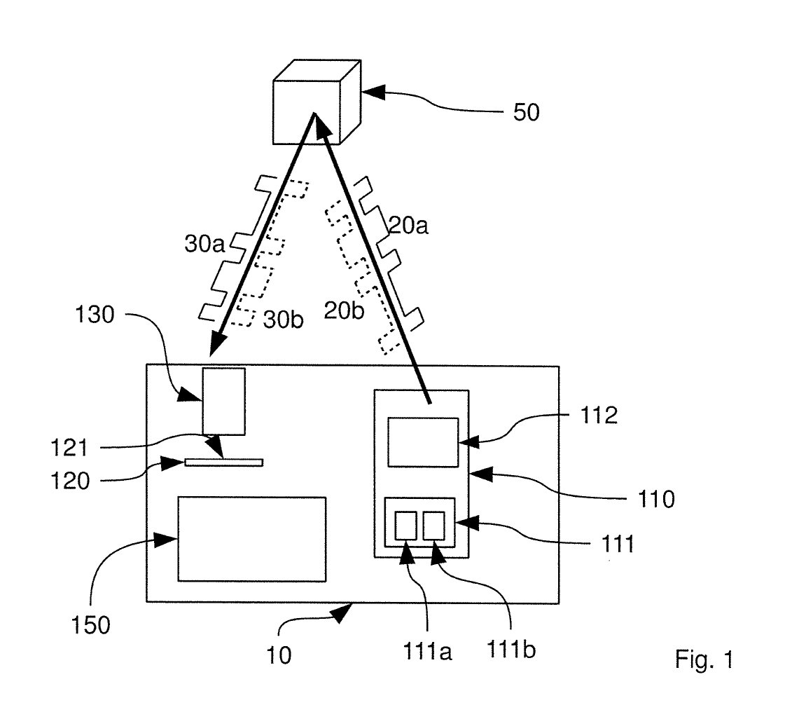

FIG. 1 shows block-diagrammatically an embodiment of the apparatus and the method. The structured light imaging system 10 includes a light projector 110, an image sensor 120, an optical system 130, and a controller 150, in order to acquire images of an object 50 in a scene. The optical system 130 typically includes an imaging optics and an optical bandpass filter to block unwanted light. The image sensor 120 includes an array of pixels 121. The projector 110 includes a light emitting component 111, e.g. a VCSEL (VCSEL: Vertical Cavity Surface Emitting Lasers) array, which has a first group of light emitters 111a and a second group of light emitters 111b. All light of the light emitters is projected by a light projecting device 112 towards the scene. The light projecting device 112 may comprise lenses, masks and/or diffractive optical elements.

The two groups of light emitters 111a, 111b are controlled by the controller 150. Further, the controller 150 synchronizes the two groups of light emitters 111a, 111b with the image sensor 120 and the pixels 121.

The light emitters are, e.g., vertical cavity surface emitting lasers (VCSEL) on a VCSEL array. A structured light imaging system 10 with a light emitting component 110 based on a VCSEL array but without separating the emitters into different groups that can be operated individually as proposed by the present patent application have been published by US2013/0038881A1 and WO2013127974A1.

According to FIG. 1, the light output of the structured light imaging system 10 corresponds to a first structured light emission 20a from the projector 110, when light output is originated from the first group of light emitters 111a. The emitted structured light when first group of light emitters 20a is on reaches the object 50, is reflected by object 50 and part of the first reflected light 30a reaches the optical system 130 of the structured light imaging system 10. The optical system 130 images the first reflected light 30a onto the pixels 121 of the image sensor 120. The light output of the structured light imaging system 10 corresponds to the second light output 20b from the projector 110, when the light output is originated from the second group of light emitters 111b. The emitted structured light when second group of light emitters 20b is on reaches the object 50, is reflected by object 50 and part of the second reflected light 30b reaches the optical system 130 of the structured light imaging system 10. The optical system 130 images the second reflected light 30b onto the pixels 121 of the image sensor 120. The wavelength of the emitted light is, e.g., between 800 nm and 1000 nm, but may also be in the visible, infrared or UV range.

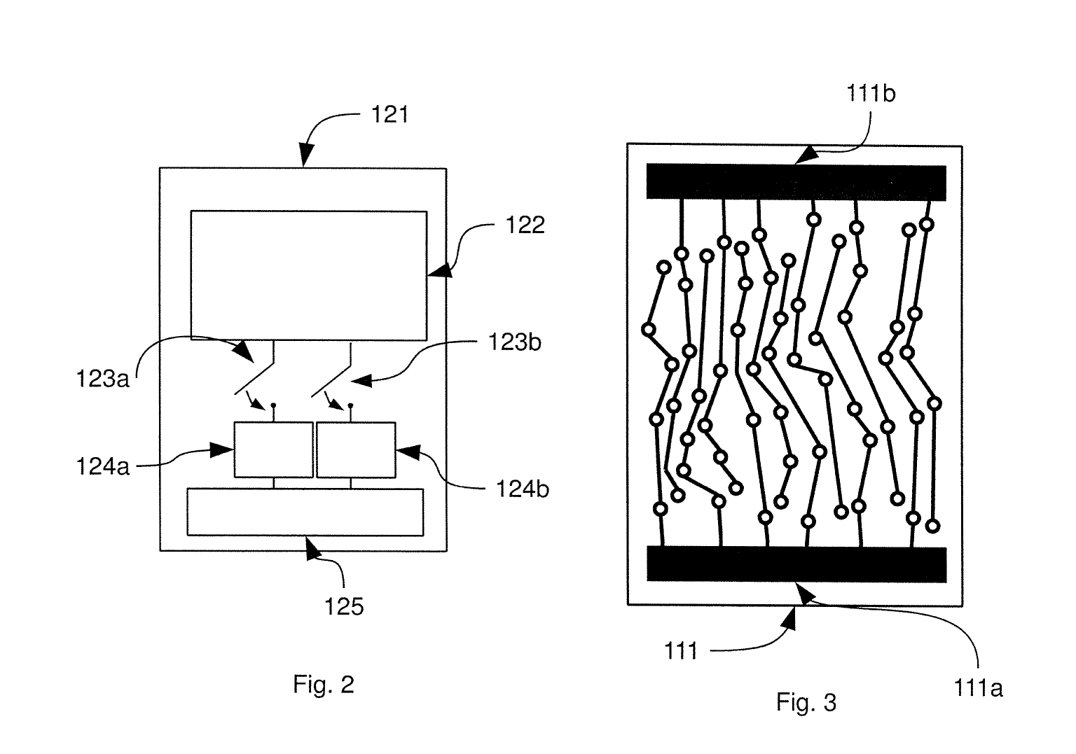

An embodiment of a pixel 121 of the image sensor 120 is presented in FIG. 2. The pixel 121 includes a photo-sensitive area 122. The photo-generated charges underneath the photo-sensitive area can be transferred via a first switch 123a into a first storage node 124a or via a second switch 123b into a second storage node 124b.

Some pixel implementations further include a third switch to dump unwanted charges, e.g. during readout or idle times. In the illustrated embodiment, the pixel 121 further includes a signal processing circuitry 125 that performs subtraction of signals, more specifically, determining a difference between charges stored in the first storage node 124a and charges stored in the second storage node 124b.

The subtraction or common mode charge removal (common-mode signal removal) may happen continuously during exposure, several times during exposure or at the end of the exposure before reading out the signals. A structured light imaging system using similar pixel architectures has been presented in EP2519001A2, where all light during the emission of structured light is transferred to the first storage node 124a of the pixels 121 on the image sensor 120 and where during an equal time duration, the emission of structured light being turned off and only the background light signal is transferred to the second storage node 124b of the pixels 121 on the image sensor 120. This on/off cycles could be repeated many times, and the signals are integrated in the first and second storage nodes of the pixels, respectively.

By doing the subtraction or common signal removal (common-mode signal removal) in the two storage nodes of each pixel, the background signal can be cancelled early on in the signal processing path. Other pixel architectures containing such pixel architectures, i.e. with pixels with a single photo-sensitive area, connected by a first switch to a first storage node and by a second switch to a second storage node, are well known in pixels used in time-of-flight depth imaging and fluorescence lifetime microscopy. Such pixel architectures have been published e.g. in patents U.S. Pat. No. 5,856,667, EP1009984B1, EP1513202B1 and U.S. Pat. No. 7,884,310B2.

An embodiment of the present invention proposes to synchronise the two groups of light emitters 111a, 111b and the two switches 123a, 123b by the controller 150. In a first phase, the first group of light emitters 111a is turned on, the second group of light emitters 111b is turned off. During this time, all photo generated charges from the photo-sensitive area 122 of the pixels 121 on the image sensor 120 are transferred to the first storage nodes 124a by the switch 123a. In a second phase, the second group of light emitters 111b is turned on, the first group of light emitters 111a is turned off. Now, all photo-generated charges from the photo-sensitive area 122 of the pixels 121 on the image sensor 120 are transferred to the second storage nodes 124b by the switch 123b.

The cycle of the first and the second phase may be repeated many times. In particular, the duration of the first phase can be the same as the duration of the second phase in the same cycle. In general, the phase duration may change from cycle to cycle. By doing so, temporal coding of the cycles is possible and e.g. orthogonal modulation schemes can be applied to avoid interferences between different structured light imaging systems 10. Faster cycling, meaning shorter phase duration, generally shows improved performance in case of fast moving objects in the scene. Phase durations typically are in the order of a few hundreds of nanoseconds up to a few hundreds of microseconds. Dependent on the applications, as many as up to a million cycles may be repeated for a single exposure and their signals integrated in the two storage nodes.

The signal processing circuitry 125 in the pixels 121 may include some common light signal removal capability (common-mode signal removal capability). Such common signal removal feature in the pixel 121 may tremendously increase the dynamic range of the structured light imaging system 10 and increases background light robustness.

After the exposure with all the cycles, the data is read out from the pixels 121 of the image sensor 120 to the control unit 150, where a depth image of the imaged object 50 in the environment can be derived from the data.

An illustrative implementation of a light emitting component 111 is sketched in FIG. 3. The light emitting component 111 includes a first group of light emitters 111a and a second group of light emitters 111b. Both groups of light emitters 111a, 111b can be controlled differently. Having such a different control of the two different groups, allows to alternately controlling, in particular operating, each group of light emitters during exposure and to synchronise it with the allocations to different storage nodes (124a, 124b) on the pixels (121). The emitted random dot pattern from the first group of light emitters 111a and the second group of light emitters 111b can be projected onto the object 50 in the scene without any emitted dot originating from the first group of light emitters 111a interfering with any dot originating from the second group of light emitters 111b. This can be achieved if the light of the two groups of light emitters are projected by the same light projecting device 112 into the space. The light projecting device 112 typically includes one or several lens elements, masks and/or diffractive optical elements.

In one embodiment, the light emitting component 111 is built on a first group of vertical cavity surface emitting laser (VCSEL) and a second group of VCSEL on the same emitting die. The first and second group of light emitters can be physically interlaced. Further, the first and second group of light emitters (111a, 111b) may be arranged to emit the same structured light pattern, e.g. the same random dot pattern, but the first emitted structured light pattern being laterally displaced with respect to the second emitted structured light pattern. In other situations, it may be provided that the two groups of light emitters (111a, 111b) are arranged to emit different structured light pattern such as a random dot pattern and a stripe-shaped pattern, or two different random dot patterns.

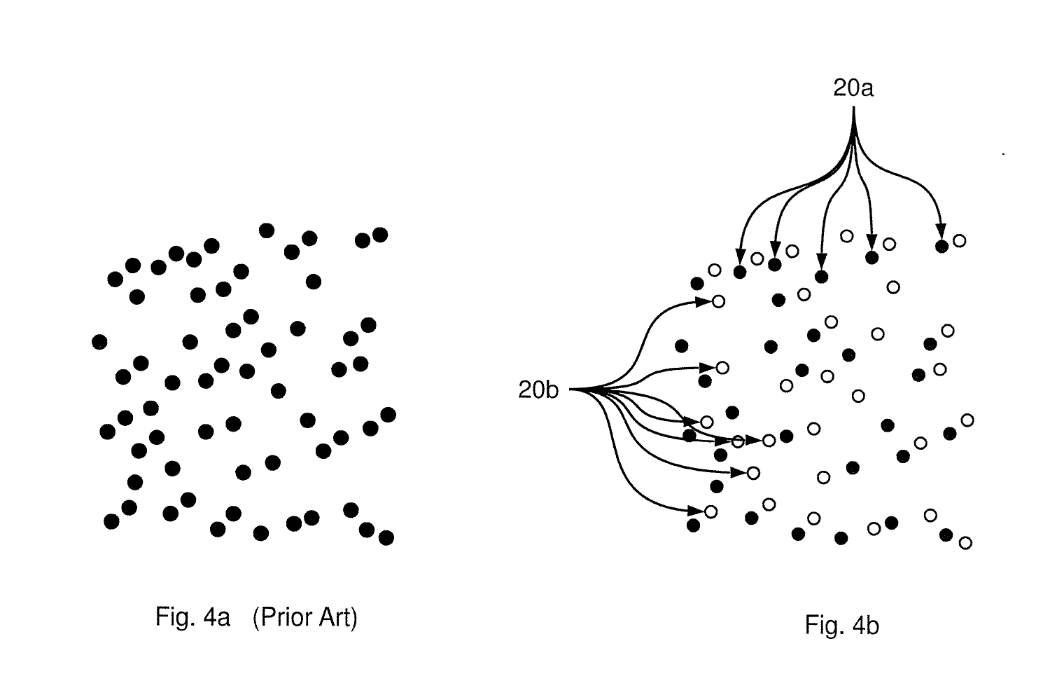

The images of FIG. 4a and FIG. 4b correspond to the light emitting component illustrated in FIG. 3. FIG. 4a illustrates the emitted structured light emission when all light emitters are turned on and controlled equally. The dots emitted by the two different groups of light emitters (111a, 111b) cannot be distinguished. The resulting emitted light pattern as illustrated in FIG. 4a corresponds to a random dot pattern as it is state-of-the-art in structured light imaging and as it has been published e.g. by PCT publication WO2007/105205A2. FIG. 4b however, illustrates a possible emission pattern according to an embodiment. The emitted light when the first group of light emitters 20a is turned on is represented as open circles, while the emitted light when the second group of light emitters is turned on 20b is represented as black dots.

For illustration purposes, the example is limited to a random dot pattern for each one of the group of light emitters. However, many different structured light patterns and their combinations are possible implementation of the invention. In case of random dot patterns, the second group of light emitters 111b may have the same pattern as the first, but it is laterally displaced with respect to the first group of light emitters 111a, and it can be operated individually.

As an example, during a first phase the first group of light emitters 111a is turned on (open circles) and the photo-charges acquired by the image sensor 120 are transferred to the first storage node 124a by the first switch 123a on the pixel 121, cf. FIG. 2. In a second phase, the second group of light emitters 111b is turned on, and the charges acquired by the image sensor 120 are transferred by the second switch 123b to the second storage 124b on the pixel 121. These two phases may again be repeated many times during a single exposure, with possibly varying phase durations to reduce interferences with other structure light imaging systems 10 and reduce artefacts on the acquisition of fast moving objects 50 in the scene. The pixels 121 may further have an in-pixel common signal removal circuitry, which makes the structured light imaging system 10 more robust in terms of background suppression.

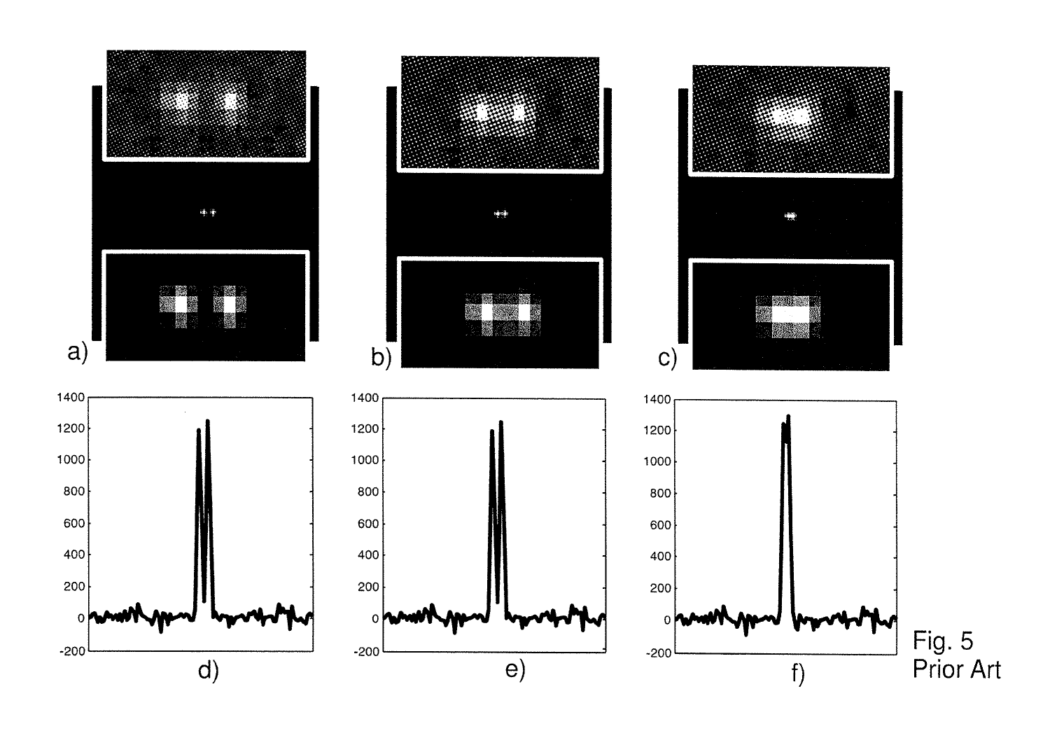

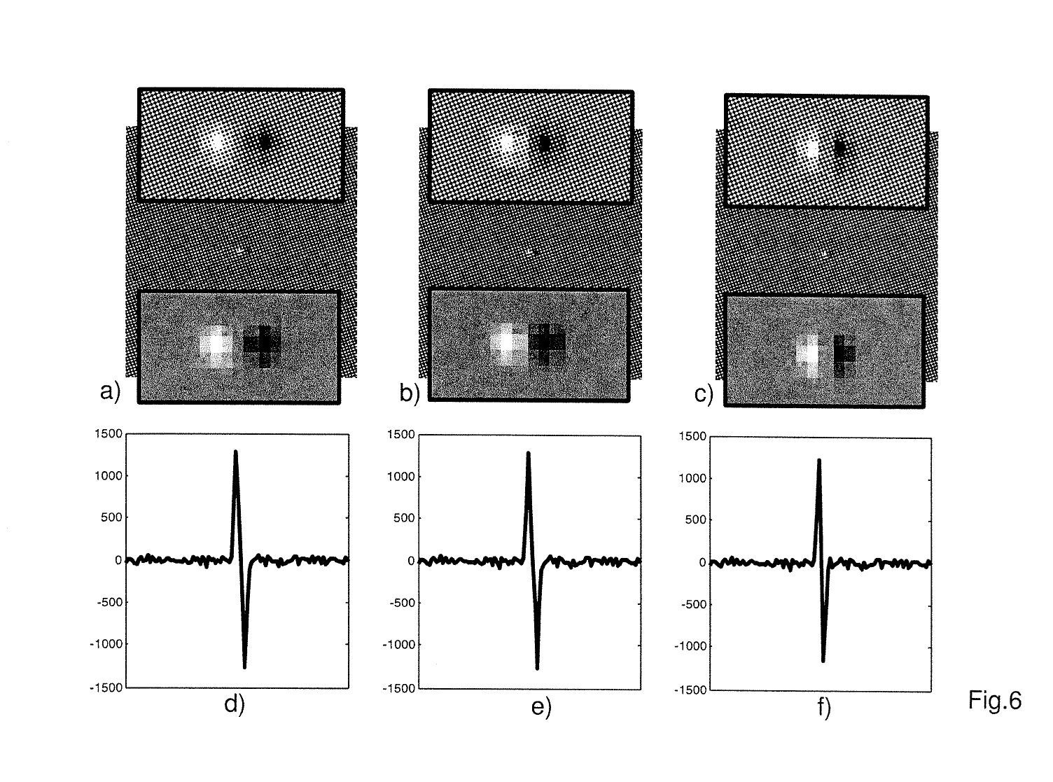

The image series of FIG. 5 and FIG. 6 illustrate a possible advantage of the present invention compared to state-of-the art structured light imaging systems. The advantage is illustrated with reference to an image of two neighbouring dots. In FIGS. 5a-c and 6a-c, insets are provided which show an enlarged detail of the corresponding images for improved clarity (top: rastered black-and-white, bottom: greyscale).

In the image series of FIG. 5, the results of a state-of-the-art structured light imaging system is sketched. In this image series, the two dots in the images originate from the same projector and the same light emitting component. Both dots are emitted simultaneously by the projector; the signals of both dots are simultaneously integrated on the pixels of the image sensor. FIG. 5a shows two dots acquired by an image sensor with a distance of with their centres of gravity being 4 pixels apart. FIG. 5d draws a horizontal signal cross-section through the dot centres from FIG. 5a. FIG. 5b illustrates the same image as in FIG. 5a, but this time, the distance between the centres of the two dots is only 3 pixels. FIG. 5e draws a horizontal cross section of the signal through the dots of FIG. 5b. FIG. 5c shows the same image as in FIG. 5a and FIG. 5b, but this time the dots are only two pixels apart. A horizontal cross-section from FIG. 5c is plotted in FIG. 5f.

At a distance of 4 pixels between the dots (FIG. 5a and FIG. 5d), the dots can clearly be distinguished and identified in the image. However, if the dots get closer to each other, the distinction gets more and more difficult (FIG. 5b and FIG. 5e), and the dots cannot be distinguished at all when they are only 2 pixels apart (FIG. 5c and FIG. 5f). This means, the density of information by the structured light given by state-of-the art structured light imaging systems is limited.

FIG. 6 shows a series of results based on a specific embodiment. In a first phase of the exposure, a first group of light emitters 111a is turned on and all photo-charges are transferred by the first switch 123a to the first storage node 124a on the pixels 121 on the image sensor 120 (cf. also FIG. 2). In a second phase, a second group of light emitters 111b is turned on and all photo-charges are transferred by the second switch 123b to the second storage node 124b on the pixels 121 on the image sensor 120. This cycle of the two phases can be repeated many times during exposure. For illustration purposes, the number of dots in the images is reduced to two dots only. The first dot is the signal integrated during the first phases of all the cycles during the exposure, the second dot is the signal integrated during the second phases of all the cycles during the exposure.

In the illustrated case, it is assumed the pixels 121 comprise a common signal removing circuitry in its signal processing circuitry 125 to subtract a common level of the signals from the first and second storage nodes 124a, 124b (cf. FIG. 2). The resulting images therefore are differential images of the first storage nodes 124a of the pixels 121 and the second storage nodes 124b of the pixels 121.

The resulting differential image has a value around zero if only background light is present (after common signal removal only noise remains), and it has positive signals for dots originating from the first group of light emitters 111a and negative signals from dots originating from the second group of light emitters 111b. The images of FIG. 6a to c, each shows the two dots of the resulting differential imaging according to this embodiment. FIG. 6a shows the image of the dot originating from an emitter of the first group of light emitters 111a and the dot originating from an emitter of the second group of light emitters 111b. The centres of gravity of the two dots are 4 pixels apart. FIG. 6d plots a horizontal cross-section through the centres of the dots. FIG. 6b shows the same dots as in FIG. 6a, but with the two dots being 3 pixels apart. FIG. 6e plots a horizontal cross-section of the signal with the dot centres. FIG. 6c shows the same dots as in FIG. 6a and FIG. 6b, but with a distance of the centres reduced to 2 pixels. FIG. 6f plots a horizontal cross-section of the signal through the dot centres. The two dots are easily distinguishable even with a distance as short as 2 pixels between the dots.

The image series of FIG. 6 and FIG. 5 show that the dots are much better distinguishable for the structured light imaging system 10 belonging to FIG. 6 than for the state-of-the art structured light imaging system belonging to FIG. 5. This example shows that the density of information that can be packed in a structured light as herein disclosed can be higher than the density of information that can be packed in prior art structured light imaging systems. The result is a gain in depth and lateral resolution, or the use of an image sensor with lower pixel counts, which reduces system complexity, image processing resources and cost.

The following embodiments are furthermore disclosed:

Structured light imaging system embodiments (structured light imaging apparatus embodiments):

E1. A structured light imaging system (10) including an image sensor (120) and a projector (110), wherein the projector (110) includes at least two groups of light emitters (111a, 111b), wherein a controller (150) is configured to enable that each group is operated individually.

E2. The structured light imaging system (10) according to embodiment E1, wherein a single light projecting device (112) of the projector (110) is configured to project structured light emitted by the at least two groups of light emitters (111a, 111b) onto a scene.

E3. The structured light imaging system (10) according to embodiment E1 or E2, wherein the at least two groups of light emitters (111a, 111b) include vertical cavity surface emitting lasers (VCSEL).

E4. The structured light imaging system (10) according to one of embodiments E1 to E3, wherein the at least two groups of light emitters (111a, 111b) are arranged on a single die.

E5. The structured light imaging system (10) according to one of embodiments E1 to E4, wherein the at least two groups of light emitters (111a, 111b) are arranged physically interlaced.

E6. The structured light imaging system (10) according to one of embodiments E1 to E5, wherein the at least two groups of light emitters (111a, 111b) are arranged to emit the same, but displaced structured light pattern.

E7. The structured light imaging system (10) according to one of embodiments E1 to E6, wherein the at least two groups of light emitters (111a, 111b) are arranged to emit different structured light pattern.

E8. The structured light imaging system (10) according to one of embodiments E1 to E7, wherein the controller (150) is configured to enable that the at least two groups of light emitters (111a, 111b) are operated in an interleaved mode.

E9. The structured light imaging system (10) according to one of embodiments E1 to E8, wherein the image sensor (120) includes an array of pixels (121), each pixel (121) having a separate storage node (124a, 124b) per group of light emitters (111a, 111b).

E10. The structured light imaging system (10) according to one of embodiments E1 to E9, wherein the controller (150) is configured to enable that for each pixel (121) of the image sensor (120) one storage node (124a, 124b) per group of light emitters (111a, 111b) is allocated.

E11. The structured light imaging system (10) according to one of embodiments E1 to E10, wherein the pixels (121) of the image sensor (120) include a common signal removal circuitry configured to remove a common-mode signal of the storage nodes (124a, 124b) of the pixels (121) on the image sensor (120).

E12. The structured light imaging system (10) according to one of embodiments E1 to E11, wherein the controller (150) is configured to enable that at least two groups of light emitters (111a, 111b) are turned on alternately and repetitively during exposure, wherein the signal is integrated correspondingly on the allocated storage nodes (124a, 124b) of the pixels (121).

E13. The structured light imaging system (10) according to one of embodiments E1 to E12, wherein the pixels (121) of the image sensor (120) are time-of-flight pixels.

Structured light imaging method embodiments:

E14. A structured light imaging method using an image sensor (120) and a projector (110) wherein the projector (110) includes at least two groups of light emitters (111a, 111b), each group of light emitters being operated individually.

E15. The structured light imaging method according to embodiment E14, wherein structured light emitted by the at least two groups of light emitters (111a, 111b) is projected through a single light projecting device (112) onto the scene.

E16. The structured light imaging method according to embodiment E14 or E15, wherein the at least two groups of light emitters (111a, 111b) are operated in an interleaved mode.

E17. The structured light imaging method according to one of embodiments E14 to E16, wherein for each pixel (121) of the image sensor (120) one storage node (124a, 124b) per group of light emitters (111a, 111b) is allocated.

E18. The structured light imaging method according to one of embodiments E14 to E17, wherein a common-mode signal of the storage nodes of the image sensor is removed.

E19. The structured light imaging method according to one of embodiments E14 to E18, wherein the at least two groups of light emitters (111a, 111b) are turned on alternately and repetitively during exposure, wherein the signal is integrated correspondingly in the allocated storage nodes (124a, 124b) of the pixels (121).

### LIST OF REFERENCES

10 structured light imaging system

110 projector

111 light emitting component

111a/b first/second group of light emitters

112 light projecting device

130 optical system

120 image sensor

121 pixel

122 photo-sensitive area

123a/b first/second switch

124a/b first/second storage node

125 signal processing circuitry

150 controller

50 object

20a emitted structured light when 1^{st} group of light emitters is on

20b emitted structured light when 2^{nd} group of light emitters is on

30a reflected light when 1^{st} group of light emitters is on

30b reflected light when 2^{nd} group of light emitters is on

1. A structured light imaging apparatus comprising a projector comprising at least two groups of light emitters for emitting structured light, an image sensor for sensing light originating from the projector, and a control unit, wherein the controller is structured and configured for individually operating each group of the at least two groups of light emitters.

2. The structured light imaging apparatus according to claim 1, the projector comprising only a single light projecting device, and the light projecting device being structured and arranged for projecting structured light emitted by the at least two groups of light emitters onto a scene.

3. The structured light imaging apparatus according to claim 1 or 2, wherein the at least two groups of light emitters comprise vertical cavity surface emitting lasers, in particular wherein each of the at least two groups of light emitters comprises at least one vertical cavity surface emitting laser, more particularly a plurality of vertical cavity surface emitting lasers each.

4. The structured light imaging apparatus according to one of claims 1 to 3, wherein the at least two groups of light emitters are arranged on a single die.

5. The structured light imaging apparatus according to one of claims 1 to 4, wherein the at least two groups of light emitters are arranged physically interlaced.

6. The structured light imaging apparatus according to one of claims 1 to 5, wherein the at least two groups of light emitters are structured and arranged to emit the same, but displaced structured light pattern.

7. The structured light imaging apparatus according to one of claims 1 to 5, wherein the at least two groups of light emitters are structured and arranged to emit different structured light patterns.

8. The structured light imaging apparatus according to one of claims 1 to 7, wherein the controller is structured and configured for operating the at least two groups of light emitters in an interleaved mode, in particular in a mode in which only a single group of the groups of light emitters is operated at a time.

9. The structured light imaging apparatus according to one of claims 1 to 8, wherein the image sensor includes an array of pixels, each pixel (121) having a separate storage node per group of light emitters

10. The structured light imaging apparatus according to one of claims 1 to 9, wherein the image sensor includes an array of pixels comprising at least two storage nodes each, and wherein the controller is structured and configured for allocating for each of the pixels a different one of the respective storage nodes to each of the groups of light emitters.

11. The structured light imaging apparatus according to one of claims 1 to 10, wherein the image sensor includes an array of pixels, each of the pixels comprising at least two storage nodes and a common signal removal circuitry, in particular wherein each of the common signal removal circuitries is configured for removing a common-mode signal from the respective storage nodes.

12. The structured light imaging apparatus according to one of claims 1 to 11, wherein the image sensor includes an array of pixels, each of the pixels comprising at least two storage nodes, and wherein the controller is configured for repetitively alternately turning on different ones of the groups of light emitters during an exposure and for synchronizing therewith an allocation of different ones of the storage nodes in each of the pixels, in particular for collecting, in each of the pixels, in different ones of the respective storage nodes, charges originating from structured light from different ones of the groups of light emitters.

13. A structured light imaging method comprising providing a projector comprising at least two groups of light emitters, emitting structured light from the at least two groups of light emitters, wherein each of the groups of light emitters is operated individually, and sensing light originating from the projector by means of an image sensor.

14. The method according to claim 13, comprising emitting the structured light from the at least two groups of light emitters through only a single light projecting device onto the scene, in particular wherein the single light projecting device is a light projecting device of the projector.

15. The method according to claim 13 or 14, comprising operating the at least two groups of light emitters in an interleaved mode, in particular in a mode in which only a single group of the groups of light emitters is operated at a time.

16. The method according to one of claims 13 to 15, wherein the image sensor comprises an array of pixels comprising at least two storage nodes each, the method comprising for each of the pixels allocating a different one of the respective storage nodes to each of the groups of light emitters.

17. The method according to one of claims 13 to 16, wherein the image sensor comprises an array of pixels comprising at least two storage nodes each, the method comprising removing, in each of the pixels, a common-mode signal from the respective storage nodes of the respective pixel, in particular wherein each of the pixels comprises a common signal removal circuitry for the common-mode signal removal.

18. The method according to one of claims 13 to 17, comprising repetitively alternately turning on different ones of the groups of light emitters during an exposure.

19. The method according to claim 18, wherein the image sensor comprises an array of pixels comprising at least two storage nodes each, the method comprising synchronizing with the repetitively alternately turning on of different ones of the groups of light emitters during an exposure an allocation of different ones of the storage nodes in each of the pixels.

20. The method according to claim 19, comprising, in each of the pixels, collecting, in different ones of the respective storage nodes, charges originating from structured light from different ones of the groups of light emitters.

21. A method for depth mapping of a scene, comprising
illuminating the scene with structured light from a projector comprising at least a first and a second group of light emitters;
the illuminating comprising operating each of the groups of light emitters individually;
detecting light portions of the structured light reflected from the scene;
determining a depth map of the scene from the detected light portions.

22. The method according to claim 21, comprising determining a difference between detected light portions originating from the first group of light emitters and detected light portions originating from the second group of light emitters.

23. A method for depth mapping of a scene, comprising
illuminating the scene with structured light by the aid of a structured light imaging apparatus according to one of claims 1 to 12;
detecting light portions of the structured light reflected from the scene by the aid of the structured light imaging apparatus;
determining a depth map of the scene from the detected light portions.

24. A depth mapping apparatus for determining a depth map of a scene, the apparatus comprising a structured light imaging apparatus according to one of claims 1 to 12 for illuminating the scene with structured light and for detecting light portions of the structured light reflected from the scene, and a processing unit for determining the depth map of the scene from the detected light portions, in particular wherein the processing unit is comprised in the controller of the structured light imaging apparatus.
